(19) United States
(12) Patent Application Publication
(10) Pub. No.: US 2011/0232950 A1
(43) Pub. Date: Sep. 29, 2011

(54) SUBSTRATE AND METHOD FOR MANUFACTURING THE SAME

(76) Inventors: Shao-Chung HU, Xindian City (TW); Ming-Chi Kan, Rende Township (TW); Chien-Min Sung, Danshui Township (TW)

(21) Appl. No.: 12/836,393

(22) Filed: Jul. 14, 2010

(30) Foreign Application Priority Data
Mar. 25, 2010 (TW) 099108884

(51) Int. Cl. H05K 1/09; H05K 1/00; C23F 1/02

(52) U.S. Cl. 174/257; 174/250; 216/13; 216/20

(57) ABSTRACT

The present invention relates to a method for manufacturing a substrate, including: providing a metal base; forming an oxide layer on one surface of the metal base; forming a chemical barrier layer on the oxide layer; forming an intermediate layer on the chemical barrier layer; forming a first metal layer on the intermediate layer; and removing parts of the intermediate layer and the first metal layer by etching to form a first metal wiring layer. Moreover, the present invention may include the following steps alternatively: laminating an insulating adhesive layer and a second metal layer on an exposed area of the chemical barrier layer; forming a second metal wiring layer by etching a part of the second metal layer; forming a surface metal layer; and forming a chip layer on the surface metal layer. The present invention also provides a structure of a substrate obtained according to the aforementioned method.

### BACKGROUND OF THE INVENTION

1. Field of the Invention

The present invention relates to a substrate and a method for manufacturing the same and, more particularly, to a manufacturing method and a structure of a substrate in which metal wiring is fabricated on a base.

2. Description of Related Art

Currently, in accordance with the development of electronics, the demand for electronic products increases and the design trend of electronic products is towards multifunction and high-performance. In particular, the kinds and usage of portable electronic products increase, resulting in the minimization of electronic products in size and weight, and thereby the design of the substrate and metal wiring used in electronic products has become more important. Accordingly, issues about the insulation between a base and metal wiring and the influence of wet etching on a base during fabricating metal wiring has become more critical.

Conventionally, in the case of fabricating metal wiring on a surface of a metal base (such as an aluminum base), the aluminum base is often corroded by a subsequent etching process, thus reducing the practicability of the aluminum base. In order to resolve the problem, the metal wiring may be fabricated by coating a metal paste if an aluminum base is used. However, some problems, such as low conductivity of the metal wiring fabricated in this manner and being unable to fabricate desired metal wiring, limit substantially the application of such method.

Taiwan patent application No. 94117337 discloses a casing for a portable electronic device and a method for fabricating the same, in which a diamond-like carbon film is formed on a surface of an aluminum base to protect the casing of the electronic device. However, the art of the above-mentioned application is not applied in a circuit substrate. Additionally, Taiwan patent application No. 94221298 discloses a technology of disposing an insulating heat dissipation layer on a surface of a thermal conductive base, in which the thermal conductive base may be made of a metal material or a ceramic material, and the insulating heat dissipation layer may be made of a ceramic material or carbon nano tubes. However, in the case of applying the structure disclosed by the above-mentioned application in a substrate and a process for fabricating metal wiring, the problem of the base being corroded by wet etching still cannot be resolved and the electrical insulation between metal wiring and the base cannot be efficiently enhanced.

Accordingly, it is important to improve the manufacturing method of a substrate to enhance the electrical insulation between metal wiring and a base and to prevent the metal base from being damaged by wet etching in a subsequent process for fabricating metal wiring, thus enhancing the practicability of fabricating metal wiring on a base.

### SUMMARY OF THE INVENTION

The object of the present invention is to provide a substrate and a method for manufacturing the same to enhance electrical insulation between a metal base and a metal wiring layer formed by a subsequent process and to prevent the metal base from being damaged by wet etching in a subsequent process for forming metal wiring, such that the conventional problem of a wiring film cannot being formed on a metal base can be resolved.

To achieve the object, the present invention provides a method for manufacturing a substrate, including: providing a metal base; forming an upper oxide layer on one surface of the metal base; forming an upper chemical barrier layer on the upper oxide layer; forming an upper intermediate layer on the upper chemical barrier layer; forming a first upper metal layer on the upper intermediate layer, in which the first upper metal layer may be made of copper or an alloy thereof; removing parts of the upper intermediate layer and the first upper metal layer by wet etching or mask etching to form a first upper metal wiring layer; optionally forming an upper surface metal layer of nickel, gold, silver, tin or an alloy thereof on the first upper metal wiring layer by surface treatment to enhance adhesion between the first upper metal wiring layer and an upper chip layer; and optionally forming an upper chip layer on a part of the upper surface metal layer. In addition, according to practical requirements, the method of the present invention may further include: forming a lower oxide layer on the other surface of the metal base; forming a lower chemical barrier layer on the lower oxide layer; forming a lower intermediate layer on the lower chemical barrier layer; forming a first lower metal layer on the lower intermediate layer, in which the first lower metal layer may be made of copper or an alloy thereof; removing parts of the lower intermediate layer and the first lower metal layer by wet etching or mask etching to form a first lower metal wiring layer; optionally forming a lower surface metal layer made of nickel, gold, silver, tin or an alloy thereof on the first lower metal wiring layer by surface treatment to enhance adhesion between the first lower metal wiring layer and a lower chip layer; and optionally forming a lower chip layer on a part of the lower surface metal layer. Herein, according to the method of the present invention, metal wiring may be fabricated at both sides of a metal base, and a plurality of through holes may be formed through the metal base, the upper oxide layer, the lower oxide layer, the upper chemical barrier layer and the lower chemical barrier layer to enhance heat dissipation if necessary.

Also, the present invention further provides a method for manufacturing another substrate, including: providing a metal base; forming an upper oxide layer on one surface of the metal base; forming an upper chemical barrier layer on the upper oxide layer; forming an upper intermediate layer on the upper chemical barrier layer; forming a first upper metal layer on the upper intermediate layer, in which the first upper metal layer may be made of copper or an alloy thereof; removing parts of the upper intermediate layer and the first upper metal layer by wet etching or mask etching to form a first upper metal wiring layer and expose a part of the upper chemical barrier layer; laminating an upper insulating adhesive layer and a second upper metal layer on an exposed area of the upper chemical barrier layer; removing parts of the second upper metal layer by etching to form a second upper metal wiring layer; optionally forming an upper surface metal layer on surfaces of the first upper metal wiring layer and the second upper metal wiring layer; and optionally forming an upper chip layer on a part of the upper surface metal layer, in which the upper surface metal layer may be made of nickel, gold, silver, tin or an alloy thereof. In addition, according to practical requirements, the method of the present invention may further include: forming a lower oxide layer on the other surface of the metal base; forming a lower chemical barrier layer on the lower oxide layer; forming a lower intermediate layer on the lower chemical barrier layer; forming a first lower metal layer on the lower intermediate layer, in which the first lower metal layer may be made of copper or an alloy thereof; removing parts of the lower intermediate layer and the first lower metal layer by wet etching or mask etching to form a first lower metal wiring layer and expose a part of the lower chemical barrier layer; laminating a lower insulating adhesive layer and a second lower metal layer on an exposed area of the lower chemical barrier layer; removing parts of the second lower metal layer by etching to form a second lower metal wiring layer; optionally forming a lower surface metal layer on surfaces of the first lower metal wiring layer and the second lower metal wiring layer; and optionally forming a lower chip layer on a part of the lower surface metal layer, in which the lower surface metal layer may be made of nickel, gold, silver, tin or an alloy thereof. Herein, according to the method of the present invention, metal wiring may be fabricated at both sides of a metal base, and a plurality of through holes may be formed through metal base, the upper oxide layer, the lower oxide layer, the upper chemical barrier layer and the lower chemical barrier layer to enhance heat dissipation if necessary. In other words, according to the method for fabricating metal wiring on a base of the present invention, the second upper/lower metal wiring layer can be selectively formed on the upper/lower insulating adhesive layer, such that the electrical insulation between the second upper/lower metal wiring layer and the metal base therebelow can be enhanced.

If necessary, the method of the present invention may further include: forming a solder mask over the first and/or second upper/lower metal wiring layer. The kind of the solder mask is not limited, but preferably is a diamond-like carbon layer to enhance heat dissipation and durability of the entire structure in which metal wiring is fabricated on a base.

According to the method of the present invention, the upper/lower intermediate layer may be formed on the upper/lower chemical barrier layer by evaporation or sputtering. The upper/lower intermediate layer is not limited in its material and is used for enhancing the adhesion between the upper/lower chemical barrier layer and the first upper/lower metal wiring layer or the upper/lower chip layer fabricated in a subsequent process. Preferably, chromium, titanium, molybdenum, tungsten or an alloy thereof is applied in the upper/lower intermediate layer.

According to the method of the present invention, the material of the upper/lower insulating adhesive layer is not limited and may be any high-temperature (such as 250° C. or more) resistant thermosetting resin. Preferably, at least one thermosetting resin selected from the group consisting of epoxy resin, unsaturated polyester resin, phenolic resin, amino resin and silicone resin is applied in the upper/lower insulating adhesive layer.

Additionally, according to the method of the present invention, the metal base may be an aluminum base or an aluminum matrix composite base, and the upper/lower oxide layer formed on the metal base may be formed by anodizing the surface of the metal base or directly coating an oxide on the surface of the metal base. Preferably, the upper/lower oxide layer is made of alumina.

According to the method of the present invention, the method for forming the upper/lower chemical barrier layer is not limited. Preferably, the upper/lower chemical barrier layer is formed on the upper/lower oxide layer by chemical vapor deposition, physical vapor deposition or coating. Herein, chemical vapor deposition may include plasma enhanced chemical vapor deposition or microwave plasma chemical vapor deposition, and physical vapor deposition may include evaporation, sputtering or cathodic arc deposition.

According to the method of the present invention, the upper/lower chemical barrier layer is not limited in its kind and thickness if it can prevent the upper/lower oxide layer or the metal base from being damaged by wet etching in a subsequent process. Preferably, oxides, carbides, nitrides, epoxides, silicone or polyimide of 0.01 to 50 μm are applied in the upper/lower chemical barrier layer. Herein, examples of carbides include diamond-like carbon or diamond; examples of nitrides include aluminum nitride (AlN), silicon nitride (Si₃N₄) or boron nitride (BN); examples of oxides include silicon dioxide (SiO₂), titanium dioxide (TiO₂) or beryllium oxide (BeO). Particularly, in the case of using a diamond-like carbon film as the upper/lower chemical barrier layer, a dopant, including F, Si, N, B or a mixture thereof, may be added thereto in an amount of less than 20 atom % to enhance adhesion of the upper/lower chemical barrier layer if necessary.

According to the method of the present invention, the thickness of the upper/lower oxide layer is not particularly limited, but preferably ranges from 3 to 100 μm. The surface of the upper/lower oxide layer may be further subjected to a sealing process, in which an inorganic metal salt (such as Ni(CH₃COO)₂ or NiF₂) is used to seal the pores on the surface of the upper/lower oxide layer by hydration with the upper/lower oxide layer so as to increase insulation between the metal base and the subsequent first and/or second upper/lower metal wiring layer.

The present invention provides a substrate fabricated by the aforementioned method, including: a metal base; an upper oxide layer, formed on one surface of the metal base; an upper chemical barrier layer, formed on the upper oxide layer; an upper intermediate layer, formed on the upper chemical barrier layer; a first upper metal wiring layer, formed by forming a first upper metal layer on the upper intermediate layer and then removing parts of the upper intermediate layer and the first upper metal layer by wet etching or mask etching; optionally an upper surface metal layer, formed on a surface of the first upper metal wiring layer; and optionally a upper chip layer, formed on a part of the upper surface metal layer, in which the surface of the upper oxide layer may include an upper sealing structure. According to practical requirements, the substrate of the present invention may further include: a lower oxide layer on the other surface of the metal base; a lower chemical barrier layer, formed on the lower oxide layer; a lower intermediate layer, formed on the lower chemical barrier layer; a first lower metal wiring layer, formed by forming a first lower metal layer on the lower intermediate layer and then removing parts of the lower intermediate layer and the first lower metal layer by wet etching or mask etching; optionally a lower surface metal layer, formed on a surface of the first lower metal wiring layer; and optionally a lower chip layer, formed on a part of the lower surface metal layer, in which the surface of the lower oxide layer may further include a lower sealing structure. Herein, according to the substrate of the present invention, metal wiring may be fabricated at both sides of a metal base, and a plurality of through holes may be formed through the metal base, the upper oxide layer, the lower oxide layer, the upper chemical barrier layer and the lower chemical barrier layer to enhance heat dissipation if necessary.

Also, the present invention provides another substrate, including: a metal base; an upper oxide layer, formed on one surface of the metal base; an upper chemical barrier layer, formed on the upper oxide layer; an upper intermediate layer, formed on the upper chemical barrier layer; a first upper metal wiring layer, formed by forming a first upper metal layer on the upper intermediate layer and then removing parts of the upper intermediate layer and the first upper metal layer by wet etching or mask etching; an upper insulating adhesive layer and a second upper metal wiring layer, laminated on an exposed area of the upper chemical barrier layer; optionally an upper surface metal layer, formed on surfaces of the first upper metal wiring layer and the second upper metal wiring layer; and optionally an upper chip layer, formed on the upper surface metal layer, in which the surface of the upper oxide layer may further include an upper sealing structure. Additionally, according to practical requirements, the substrate of the present invention may further include: a lower oxide layer, formed on the other surface of the metal base; a lower chemical barrier layer, formed on the lower oxide layer; a lower intermediate layer, formed on the lower chemical barrier layer; a first lower metal wiring layer, formed by forming a first lower metal layer on the lower intermediate layer and then removing parts of the lower intermediate layer and the first lower metal layer by wet etching or mask etching; a lower insulating adhesive layer and a second lower metal wiring layer, laminated on an exposed area of the lower chemical barrier layer; optionally a lower surface metal layer, formed on surfaces of the first lower metal wiring layer and the second lower metal wiring layer; and optionally a lower chip layer, formed on the lower surface metal layer, in which the surface of the lower oxide layer may further include a lower sealing structure. Herein, according to the substrate of the present invention, metal wiring may be fabricated at both sides of a metal base, and a plurality of through holes may be formed through the metal base, the upper oxide layer, the lower oxide layer, the upper chemical barrier layer and the lower chemical barrier layer to enhance heat dissipation if necessary. In other words, according to the structure of the present invention, in which metal wiring is fabricated on a base, the second upper/lower metal wiring layer can be selectively formed on the upper/lower insulating adhesive layer, such that the electrical insulation between the second upper/lower metal wiring layer and the metal base therebelow can be enhanced.

According to the substrate of the present invention, the upper/lower intermediate layer is not limited in its material and is used for enhancing the adhesion between the upper/lower chemical barrier layer and the first upper/lower metal wiring layer or the upper/lower chip layer fabricated in a subsequent process. Preferably, chromium, titanium, molybdenum, tungsten or an alloy thereof is applied in the upper/lower intermediate layer. In addition, the material of the upper/lower insulating adhesive layer is not limited and may be any high-temperature (such as 250° C. or more) resistant thermosetting resin. Preferably, at least one thermosetting resin selected from the group consisting of epoxy resin, unsaturated polyester resin, phenolic resin, amino resin and silicone resin is applied in the upper/lower insulating adhesive layer. Moreover, the upper/lower surface metal layer of the present invention includes nickel, gold, tin, silver or an alloy thereof, such that the upper/lower surface metal layer can prevent the upper/lower chip layer from being damaged during high-temperature junction.

Furthermore, according to the substrate of the present invention, the metal base may be an aluminum base or an aluminum matrix composite base, and the upper/lower oxide layer formed on the metal base may be formed by anodizing the surface of the metal base or directly coating an oxide on the surface of the metal base. Preferably, the upper/lower oxide layer is made of alumina.

According to the substrate of the present invention, the upper/lower chemical barrier layer is not limited in its kind and thickness if it can prevent the upper/lower oxide layer or the metal base from being damaged by wet etching in a subsequent process. Preferably, oxides, carbides, nitrides, epoxides, silicone or polyimide of 0.01 to 50 μm are applied in the upper/lower chemical barrier layer. Herein, examples of carbides include diamond-like carbon or diamond; examples of nitrides include aluminum nitride (AlN), silicon nitride (Si₃N₄) or boron nitride (BN); examples of oxides include silicon dioxide (SiO₂), titanium dioxide (TiO₂) or beryllium oxide (BeO). Particularly, in the case of using a diamond-like carbon film as the upper/lower chemical barrier layer, a dopant, including F, Si, N, B or a mixture thereof, may be added thereto in a concentration of less than 20 atom % to enhance adhesion of the upper/lower chemical barrier layer if necessary.

According to the substrate of the present invention, the thickness of the upper/lower oxide layer is not particularly limited, but preferably ranges from 3 to 100 μm. The surface of the upper/lower oxide layer may be further subjected to a sealing process to form an upper/lower sealing structure, in which an inorganic metal salt (such as Ni(CH₃COO)₂ or NiF₂) is used to seal the pores on the surface of the upper/lower oxide layer by hydration with the upper/lower oxide layer so as to increase insulation between the metal base and the subsequent first and/or second upper/lower metal wiring layer.

Other objects, advantages, and novel features of the invention will become more apparent from the following detailed description when taken in conjunction with the accompanying drawings.

### BRIEF DESCRIPTION OF THE DRAWINGS

FIGS. 1A to 1I show a method for fabricating a substrate according to a preferred embodiment of the present invention;

FIGS. 2 and 2′ show cross-sectional views of substrate according to another preferred embodiment of the present invention;

FIGS. 3A to 3I show a method for fabricating a substrate according to a yet another preferred embodiment of the present invention; and

FIGS. 4 and 4′ show cross-sectional views of substrates according to yet another preferred embodiment of the present invention.

### DETAILED DESCRIPTION OF THE PREFERRED EMBODIMENT

Hereafter, the manufacturing method and structure of the substrate according to the present invention will be described in detail.

### Example 1

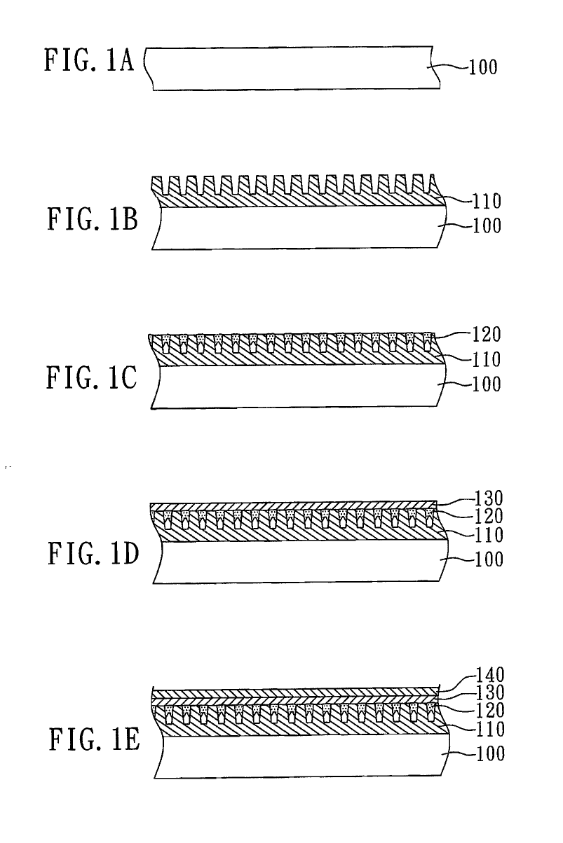

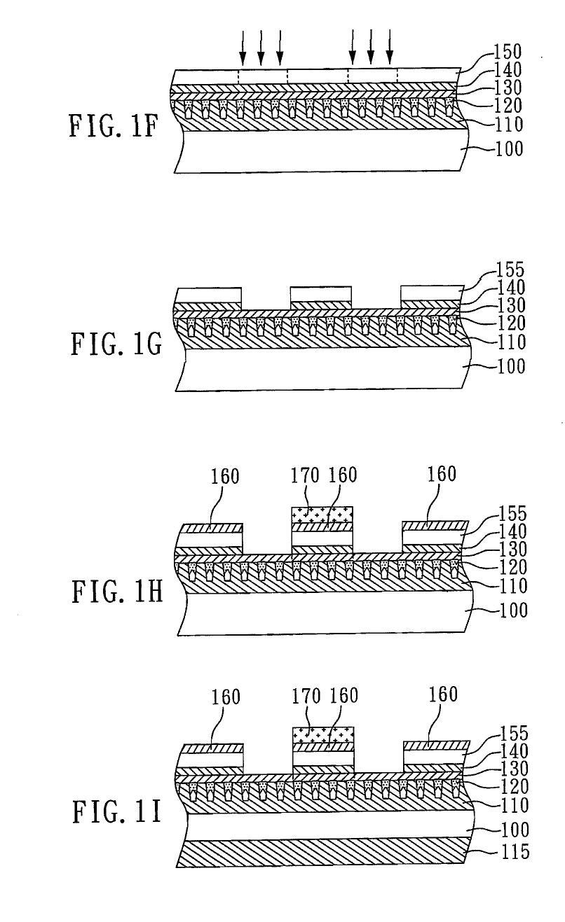

FIGS. 1A to 1H show a method for fabricating a substrate according to the present invention. First, as shown in FIG. 1A, a metal base 100 is provided. Herein, the metal base 100 may be an aluminum base or an aluminum matrix composite base. In the present example, an aluminum base is used. Subsequently, as shown in FIG. 1B, an upper oxide layer 110 is formed on a surface of the metal base 100 to increase insulation between the metal layer 100 and the subsequent first upper metal wiring layer. The upper oxide layer 110 may be formed by an electrochemical process, in which the metal base 100 is dipped into an acid solution and a surface of the metal base 100 is anodized. In other words, according to the aluminum base used in the present example, one surface of the metal base 100 can be formed as an upper oxide layer of alumina by anodization. Alternatively, the upper oxide layer 110 may be formed by another process, for example, coating an oxidizable material and then performing an electrochemical process or dipping the metal base into a solution for forming oxides (electroless).

The upper oxide layer 110 is not limited in its thickness if the insulation between the metal base 100 and the subsequent first upper metal wiring layer can be efficiently achieved. In the case of the upper oxide layer being less than 3 μm in thickness, it is difficult to efficiently provide insulation between the metal base 100 and the subsequent first upper metal wiring layer. Accordingly, in the present example, the upper oxide layer is formed in a thickness of about 3 to 100 μm.

Next, as shown in FIG. 1C, the surface of the upper oxide layer 110 is subjected to a sealing process to form an upper sealing structure 120. In the sealing process, an inorganic metal salt (such as Ni(CH₃COO)₂ or NiF₂) is used to seal the pores on the surface of the upper oxide layer 110 by hydration with the upper oxide layer 110 so as to increase insulation between the metal base 100 and the subsequent first upper metal wiring layer. According to the steps of forming the upper oxide layer and sealing pores, hydroxides such as Ni(OH)₂ or Al(OH)₃ or fluorides such as AlF₃ can be formed, resulting in generation of an upper sealing structure 120 for sealing pores on the surface of the upper oxide layer 110.

Then, as shown in FIG. 1D, an upper chemical barrier layer 130 is formed on the upper oxide layer 110. The upper chemical barrier layer 130 may be formed by chemical vapor deposition, physical vapor deposition or coating. Chemical vapor deposition includes plasma enhanced chemical vapor deposition or microwave plasma chemical vapor deposition. Physical vapor deposition includes evaporation, sputtering or cathodic arc deposition. According to the present example, the upper chemical barrier layer 130 is formed on the upper oxide layer 110 by plasma enhanced chemical vapor deposition. The upper chemical barrier layer 130 is not limited in its kind and thickness if it can prevent the upper oxide layer 110 or the metal base 100 from being damaged by wet etching in a subsequent process. Preferably, oxides, carbides, nitrides, epoxides, silicone or polyimide of 0.01 to 50 μm are used. Herein, examples of carbides include diamond-like carbon or diamond; examples of nitrides include aluminum nitride (AlN), silicon nitride (Si₃N₄) or boron nitride (BN); examples of oxides include silicon dioxide (SiO₂), titanium dioxide (TiO₂) or beryllium oxide (BeO). According to the present example, a diamond-like carbon film is used as the upper chemical barrier layer 130. In addition, if a diamond-like carbon film is used as the upper chemical barrier layer 130, as in the present example, a dopant, including F, Si, N, B or a mixture thereof, may be added thereto in less than 20 atom % to enhance adhesion of the diamond-like carbon film as the upper chemical barrier layer 130 if necessary.

Finally, as shown in FIGS. 1E to 1H, an upper intermediate layer 140 is formed on the upper chemical barrier layer 130, and a first upper metal layer 150 is formed on the upper intermediate layer 140. As shown in FIGS. 1F to 1H, by wet etching or mask etching, parts of the upper intermediate layer 140 and the first upper metal layer 150 are removed to form a first upper metal wiring layer 155. Also, the first upper metal wiring layer 155 may be subjected to surface treatment, thus forming an upper surface metal layer 160 of nickel, gold, silver, tin or an alloy thereof, to enhance the adhesion between the first upper metal wiring layer 155 and the upper chip layer 170, as shown in FIG. 1H. According to the present example, the upper intermediate layer 140 may be formed on the upper chemical barrier layer 130 by evaporation or sputtering, and the upper intermediate layer 140 is used for enhancing the adhesion between the upper chemical barrier layer 130 and the subsequent first upper metal wiring layer 155. Thereby, preferably, chromium, titanium, molybdenum, tungsten or an alloy thereof is applied in the upper intermediate layer 140. The first upper metal layer 150 may be made of copper or an alloy thereof and is subjected to wet etching or mask etching to form the first upper metal wiring layer 155, followed by formation of the upper surface metal layer 160 on the first upper metal wiring layer 155 and then forming an upper chip layer 170 on a part of the upper surface metal layer 160 to electrically connect the upper chip layer 170 and the first upper metal wiring layer 155 to each other.

Moreover, according to the present example, a lower oxide layer 115 may be selectively formed on the other surface of the metal base 100, but metal wiring is formed at only one side of the metal base 100, as shown in FIG. 1I.

According to the present example, a solder mask (not shown) may be further formed over the first upper metal wiring layer. The kind of the solder mask is not limited, but preferably is a diamond-like carbon layer to enhance heat dissipation and durability of the entire structure in which metal wiring is fabricated on a base.

### Example 2

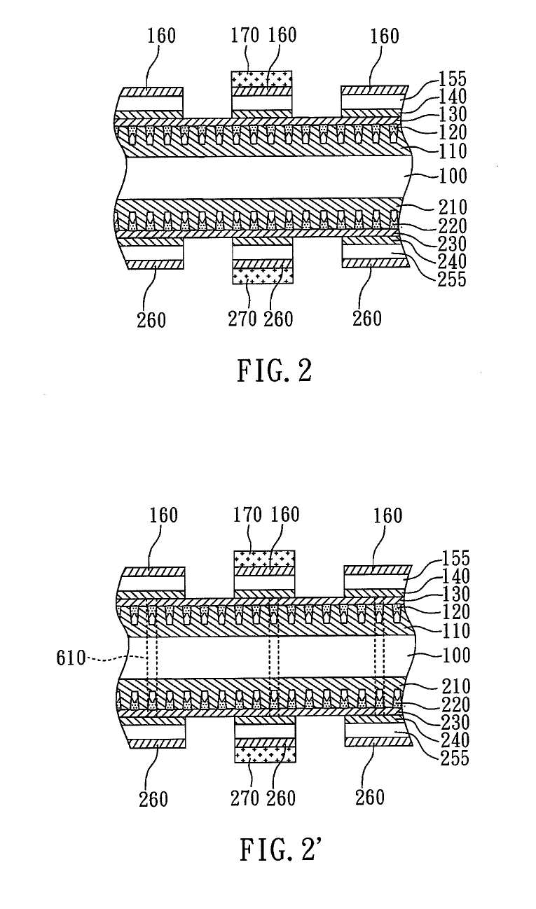

FIG. 2 shows a cross-sectional view of another substrate according to the present invention. The manufacturing method and structure of the substrate according to the present example are the same as those illustrated in the example 1, except those variations described hereafter. In the example 1, the metal wiring is formed on only one surface of the metal base 100. However, in the present example, a lower oxide layer 210, a lower chemical barrier layer 230, a lower intermediate layer 240 and a first lower metal layer are further formed on the other surface of the metal base 100. Herein, the surface of the lower oxide layer 210 may include a lower sealing structure 220, and the first lower metal layer is also subjected to wet etching or mask etching to form a first lower metal wiring layer 255. In addition, a lower surface metal layer 260 is provided on the first lower metal wiring layer 255, followed by formation of a lower chip layer 270 on a part of the lower surface metal layer 260. Herein, the method and the fabricated structure according to the present example also can achieve the object and function as described in the example 1.

Moreover, according to the present example, a plurality of through holes 610, as shown in FIG. 2′, may be selectively formed through the metal base 100, the upper oxide layer 110, the lower oxide layer 210, the upper chemical barrier layer 130 and the lower chemical barrier layer 230 to enhance heat dissipation.

### Example 3

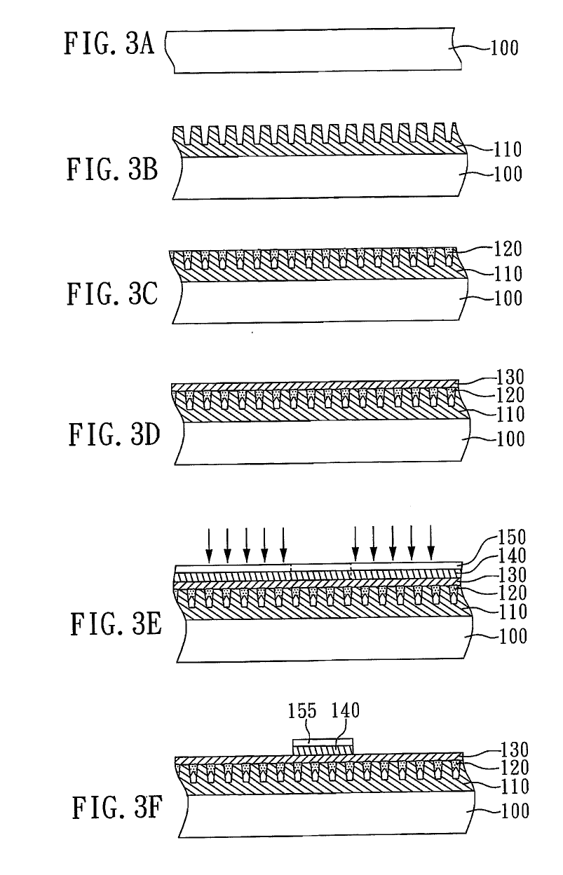

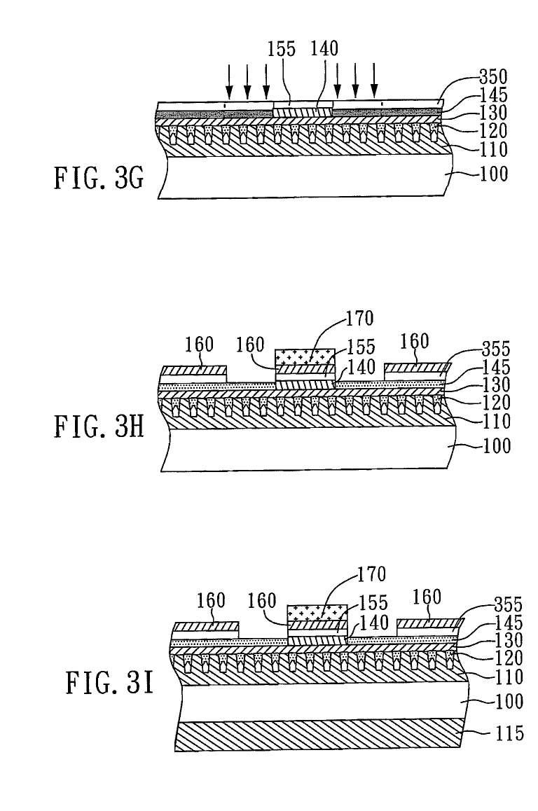

FIGS. 3A to 3H show a method for fabricating another substrate of the present invention. The steps and structures shown in FIGS. 3A to 3D are the same as those shown in FIGS. 1A to 1D of the example 1. The difference between the present example and the example 1 is shown in FIGS. 3E to 3H. As shown in FIGS. 3E to 3H, after an upper intermediate layer 140 is formed on the upper chemical barrier layer 130, and a first upper metal layer 150 is formed on the upper intermediate layer 140, parts of the upper intermediate layer 140 and the first upper metal layer 150 are removed by wet etching or mask etching to form a first upper metal wiring layer 155 and expose the upper chemical barrier layer 130. Hereafter, an upper insulating adhesive layer 145 and a second upper metal layer 350 are laminated on an exposed area of the upper chemical barrier layer 130 in sequence. Subsequently, the second upper metal layer 350 is subjected to wet etching or mask etching to form a second upper metal wiring layer 355. Finally, an upper surface metal layer 160 is formed on the surfaces of the unremoved first and second upper metal wiring layers 155, 355, and then an upper chip layer 170 is formed on a part of the upper surface metal layer 160. The above-mentioned first and second upper metal layers 150, 350 may be made of copper or an alloy thereof.

Moreover, according to the present example, a lower oxide layer 115 may be selectively formed on the other surface of the metal base 100, but the first metal wiring layer is formed at only one side of the metal base 100, as shown in FIG. 3I.

According to the present example, the material of the upper insulating adhesive layer 145 may be any high-temperature (such as 250° C. or more) resistant thermosetting resin. Preferably, at least one thermosetting resin selected from the group consisting of epoxy resin, unsaturated polyester resin, phenolic resin, amino resin and silicone resin is applied in the upper insulating adhesive layer 145. In the present example, an epoxy resin is used.

### Example 4

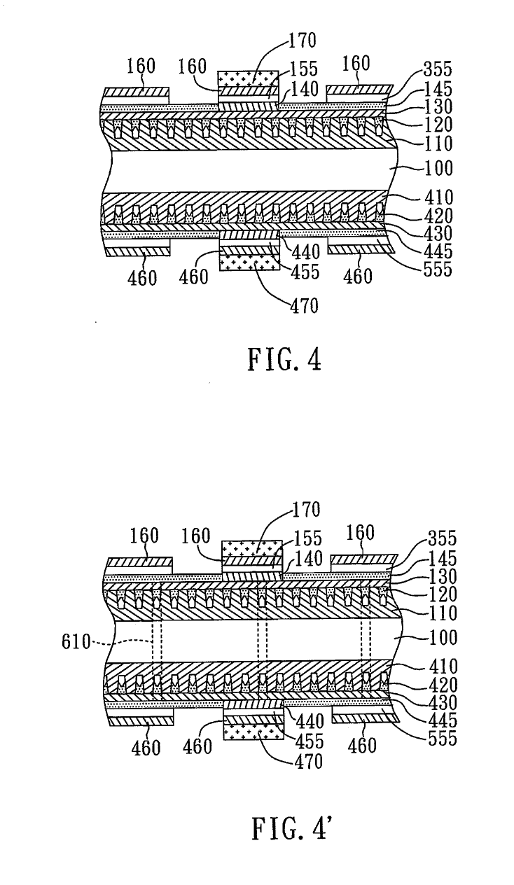

FIG. 4 shows a cross-sectional view of yet another substrate according to the present invention. The manufacturing method and structure of the substrate according to the example are the same as those illustrated in the example 3, except those variations described hereafter. In the example 3, the metal wiring is formed on only one surface of the metal base 100. However, in the present example, the substrate further includes: a lower oxide layer 410, formed on the other surface of the metal base 100; a lower chemical barrier layer 430, formed on the lower oxide layer 410; a lower intermediate layer 440, formed on the lower chemical barrier layer 430; a first lower metal wiring layer 455, formed by forming a first lower metal layer on the lower intermediate layer 440 and then removing parts of the lower intermediate layer 440 and the first lower metal layer by wet etching or mask etching; a lower insulating adhesive layer 445 and a second lower metal wiring layer 555, laminated on an exposed area of the lower chemical barrier layer 430 in sequence; a lower surface metal layer 460, formed on the surfaces of the first and second lower metal wiring layers 455, 555; and a lower chip layer 470, formed on a part of the lower surface metal layer 460. Herein, a lower sealing structure 420 is further included in the surface of the lower oxide layer. Herein, the method and the fabricated structure according to the present example also can achieve the object and function as described in the example 3.

Moreover, according to the present example, a plurality of through holes 610, as shown in FIG. 4′, may be selectively formed through the metal base 100, the upper oxide layer 110, the lower oxide layer 410, the upper chemical barrier layer 130 and the lower chemical barrier layer 430 to enhance heat dissipation.

Thereby, according to the present invention and the above-mentioned preferred examples, the manufacturing method and structure of the substrate according to the present invention can efficiently enhance insulation between the metal wiring layer and the metal base, and can prevent the metal base from being damaged by wet etching in the subsequent process for fabricating metal wiring, such that the conventional problem of a wiring film not being formable on a metal base can be resolved and the practicability of fabricating metal wiring on a base can be enhanced.

Although the present invention has been explained in relation to its preferred embodiment, it is to be understood that many other possible modifications and variations can be made without departing from the scope of the invention as hereinafter claimed.

What is claimed is:

1. A method for manufacturing a substrate, comprising:
providing a metal base;
forming an upper oxide layer on one surface of the metal base;
forming an upper chemical barrier layer on the upper oxide layer;
forming an upper intermediate layer on the upper chemical barrier layer;
forming a first upper metal layer on the upper intermediate layer; and
removing parts of the upper intermediate layer and the first upper metal layer by wet etching or mask etching to form a first upper metal wiring layer,
wherein a sealing process is performed on a surface of the upper oxide layer.

2. The method as claimed in claim 1, further comprising:
forming an upper surface metal layer on a surface of the first upper metal wiring layer; and
forming an upper chip layer on a part of the upper surface metal layer,
wherein the upper surface metal layer is made of nickel, gold, silver, tin or an alloy thereof.

3. The method as claimed in claim 1, further comprising:
laminating an upper insulating adhesive layer and a second upper metal layer on an exposed area of the upper chemical barrier layer;
removing parts of the second upper metal layer by etching to form a second upper metal wiring layer;
forming an upper surface metal layer on surfaces of the first upper metal wiring layer and the second upper metal wiring layer; and
forming an upper chip layer on a part of the upper surface metal layer,
wherein the upper surface metal layer is made of nickel, gold, silver, tin or an alloy thereof.

4. The method as claimed in claim 1, wherein the upper intermediate layer is formed on the upper chemical barrier layer by evaporation or sputtering.

5. The method as claimed in claim 1, wherein the upper oxide layer is formed by anodizing the surface of the metal base.

6. The method as claimed in claim 1, wherein the upper oxide layer is formed by coating an oxide on the surface of the metal base.

7. The method as claimed in claim 1, wherein the upper chemical barrier layer is formed on the upper oxide layer by chemical vapor deposition, physical vapor deposition or coating.

8. The method as claimed in claim 7, wherein the chemical vapor deposition is plasma enhanced chemical vapor deposition or microwave plasma chemical vapor deposition.

9. The method as claimed in claim 7, wherein the physical vapor deposition is evaporation, sputtering or cathodic arc deposition.

10. The method as claimed in claim 1, wherein the upper chemical barrier layer is made of oxide, carbide, nitride, epoxide, silicone or polyimide.

11. The method as claimed in claim 10, wherein the carbide is diamond-like carbon or diamond.

12. The method as claimed in claim 11, wherein the diamond-like carbon has a dopant therein in an amount of less than 20 atom %, and the dopant is F, Si, N, B or a mixture thereof.

13. The method as claimed in claim 10, wherein the nitride is aluminum nitride (AlN), silicon nitride (Si₃N₄) or boron nitride (BN).

14. The method as claimed in claim 10, wherein the oxide is silicon dioxide (SiO₂), titanium dioxide (TiO₂) or beryllium oxide (BeO).

15. The method as claimed in claim 1, wherein the sealing process is performed by hydration between the upper oxide layer and an inorganic metal salt.

16. The method as claimed in claim 1, wherein the inorganic metal salt is Ni(CH₃COO)₂ or NiF₂.

17. The method as claimed in claim 2, further comprising:
forming a lower oxide layer on the other surface of the metal base;
forming a lower chemical barrier layer on the lower oxide layer;
forming a lower intermediate layer on the lower chemical barrier layer;
forming a first lower metal layer on the lower intermediate layer;
removing parts of the lower intermediate layer and the first lower metal layer by wet etching or mask etching to form a first lower metal wiring layer;
forming a lower surface metal layer on a surface of the first lower metal wiring layer; and
forming a lower chip layer on a part of the lower surface metal layer,
wherein another sealing process is performed on a surface of the lower oxide layer, and the lower surface metal layer is made of nickel, gold, silver, tin or an alloy thereof.

18. The method as claimed in claim 3, further comprising:
forming a lower oxide layer on the other surface of the metal base;
forming a lower chemical barrier layer on the lower oxide layer;
forming a lower intermediate layer on the lower chemical barrier layer;
forming a first lower metal layer on the lower intermediate layer;
removing parts of the lower intermediate layer and the first lower metal layer by wet etching or mask etching to form a first lower metal wiring layer;
laminating a lower insulating adhesive layer and a second lower metal layer on an exposed area of the lower chemical barrier layer;
removing parts of the second lower metal layer by etching to form a second lower metal wiring layer;
forming a lower surface metal layer on surfaces of the first lower metal wiring layer and the second lower metal wiring layer; and
forming a lower chip layer on a part of the lower surface metal layer,
wherein another sealing process is performed on a surface of the lower oxide layer, and the lower surface metal layer is made of nickel, gold, silver, tin or an alloy thereof.

19. The method as claimed in claim 17, further comprising: forming a plurality of through holes through the metal base, the upper oxide layer, the lower oxide layer, the upper chemical barrier layer and the lower chemical barrier layer.

20. The method as claimed in claim 18, further comprising: forming a plurality of through holes through the metal base, the upper oxide layer, the lower oxide layer, the upper chemical barrier layer and the lower chemical barrier layer.

21. A substrate, comprising:
a metal base;
an upper oxide layer, formed on one surface of the metal base;
an upper chemical barrier layer, formed on the upper oxide layer;
an upper intermediate layer, formed on the upper chemical barrier layer; and
a first upper metal wiring layer, formed by forming a first upper metal layer on the upper intermediate layer and then removing parts of the upper intermediate layer and the first upper metal layer by wet etching or mask etching,
wherein a surface of the upper oxide layer comprises an upper sealing structure.

22. The substrate as claimed in claim 21, further comprising:
an upper surface metal layer, formed on a surface of the first upper metal wiring layer; and
an upper chip layer, formed on a part of the upper surface metal layer,
wherein the upper surface metal layer is made of nickel, gold, tin, silver or an alloy thereof.

23. The substrate as claimed in claim 21, further comprising:
an upper insulating adhesive layer and a second upper metal wiring layer, laminated on an exposed area of the upper chemical barrier layer;
an upper surface metal layer, formed on surfaces of the first upper metal wiring layer and the second upper metal wiring layer; and
an upper chip layer, formed on a part of the upper surface metal layer,
wherein the upper surface metal layer is made of nickel, gold, tin, silver or an alloy thereof.

24. The substrate as claimed in claim 21, wherein the upper intermediate layer comprises chromium, titanium, molybdenum, tungsten or an alloy thereof.

25. The substrate as claimed in claim 23, wherein the upper insulating adhesive layer comprises at least one thermosetting resin selected from the group consisting of epoxy resin, unsaturated polyester resin, phenolic resin, amino resin and silicone resin.

26. The substrate as claimed in claim 21, wherein the metal base is an aluminum base or an aluminum matrix composite base.

27. The substrate as claimed in claim 21, wherein the upper oxide layer is made of alumina.

28. The substrate as claimed in claim 21, wherein the upper chemical bather layer is made of oxide, carbide, nitride, epoxide, silicone or polyimide.

29. The substrate as claimed in claim 28, wherein the carbide is diamond-like carbon or diamond.

30. The substrate as claimed in claim 29, wherein the diamond-like carbon has a dopant therein in an amount of less than 20 atom %, and the dopant is F, Si, N, B or a mixture thereof.

31. The substrate as claimed in claim 28, wherein the nitride is aluminum nitride (AlN), silicon nitride (Si₃N₄) or boron nitride (BN).

32. The substrate as claimed in claim 28, wherein the oxide is silicon dioxide (SiO₂), titanium dioxide (TiO₂) or beryllium oxide (BeO).

33. The substrate as claimed in claim 21, wherein the first upper metal layer comprises copper or an alloy thereof.

34. The substrate as claimed in claim 21, wherein the thickness of the oxide layer ranges from 3 μm to 100 μm.

35. The substrate as claimed in claim 21, wherein the thickness of the chemical barrier layer ranges from 0.01 μm to 50 μm.

36. The substrate as claimed in claim 22, further comprising:
a lower oxide layer, formed on the other surface of the metal base;
a lower chemical barrier layer, formed on the lower oxide layer;
a lower intermediate layer, formed on the lower chemical barrier layer;
a first lower metal wiring layer, formed by forming a first lower metal layer on the lower intermediate layer and then removing parts of the lower intermediate layer and the first lower metal layer by wet etching or mask etching;
a lower surface metal layer, formed on a surface of the first lower metal wiring layer; and
a lower chip layer, formed on a part of the lower surface metal layer,
wherein a surface of the lower oxide layer comprises a lower sealing structure, and the lower surface metal layer is made of nickel, gold, tin, silver or an alloy thereof.

37. The substrate as claimed in claim 23, further comprising:
a lower oxide layer, formed on the other surface of the metal base;
a lower chemical barrier layer, formed on the lower oxide layer;
a lower intermediate layer, formed on the lower chemical barrier layer;
a first lower metal wiring layer, formed by forming a first lower metal layer on the lower intermediate layer and then removing parts of the lower intermediate layer and the first lower metal layer by wet etching or mask etching;
a lower insulating adhesive layer and a second lower metal wiring layer, laminated on an exposed area of the lower chemical barrier layer;
a lower surface metal layer, formed on surfaces of the first lower metal wiring layer and the second lower metal wiring layer; and
a lower chip layer, formed on a part of the lower surface metal layer,
wherein a surface of the lower oxide layer comprises a lower sealing structure, and the lower surface metal layer is made of nickel, gold, tin, silver or an alloy thereof.

38. The substrate as claimed in claim 36, further comprising: a plurality of through holes formed through the metal base, the upper oxide layer, the lower oxide layer, the upper chemical barrier layer and the lower chemical barrier layer.

39. The substrate as claimed in claim 37, further comprising: a plurality of through holes formed through the metal base, the upper oxide layer, the lower oxide layer, the upper chemical barrier layer and the lower chemical barrier layer.
